(19) United States
(12) Patent Application Publication
(10) Pub. No.: US 2023/0133258 A1
(43) Pub. Date: May 4, 2023

(54) FILM DEPOSITION APPARATUS

(71) Applicant: TOYOTA JIDOSHA KABUSHIKI KAISHA, Toyota-shi (JP)

(72) Inventor: Takayasu SATO, Takahama-shi (JP)

(73) Assignee: TOYOTA JIDOSHA KABUSHIKI KAISHA, Toyota-shi (JP)

(21) Appl. No.: 17/950,753

(22) Filed: Sep. 22, 2022

(30) Foreign Application Priority Data
Nov. 2, 2021 (JP) 2021-179734

(51) Int. Cl. C23C 14/54; C23C 14/28

(52) U.S. Cl. CPC C23C 14/541; C23C 14/28

(57) ABSTRACT

A film deposition apparatus according to an embodiment is a film deposition apparatus including a depressurized processing vessel in which a film deposition chamber and a cooling chamber communicating with the film deposition chamber are provided, the film deposition chamber being configured to perform vacuum deposition on a substrate, the cooling chamber being configured to cool the substrate. The cooling chamber includes a passage through which the substrate moves, and a cooling device placed on an inner wall of the processing vessel, the cooling device including a surface-area expansion structure portion facing the passage and a refrigerant passage for refrigerant. The surface-area expansion structure portion includes a plurality of projecting portions provided to project toward the passage from the inner wall of the processing vessel. The refrigerant passage is formed along the projecting portions.

### CROSS-REFERENCE TO RELATED APPLICATION

This application claims priority to Japanese Patent Application No. 2021-179734 filed on Nov. 2, 2021, incorporated herein by reference in its entirety.

### BACKGROUND

### 1. Technical Field

The present disclosure relates to a film deposition apparatus.

### 2. Description of Related Art

Japanese Unexamined Patent Application Publication No. 2003-247067 (JP 2003-247067 A) describes a vacuum film deposition apparatus for forming a film on a substrate placed in a vacuum case. The vacuum case is provided with a substrate arrangement portion and a film-deposition-material stay portion that are separated from each other by an openable and closable shutter 24. The substrate arrangement portion in the vacuum case is provided with a film deposition zone in which a film formation on a substrate is performed, and cooling zones placed at both ends of the deposition zone. In the cooling zones, the substrate is withdrawn from the deposition zone such that the substrate is subjected to a cooling treatment.

In the cooling zones, the substrate the temperature of which is increased due to the film deposition is cooled by being sandwiched between a cooling plate and a clamping plate. Refrigerant such as coolant circulates through the cooling plate. Further, JP 2003-247067 A has the following description. That is, as the cooling method, a method for cooling the substrate by pressing the cooling plate against the substrate may be combined appropriately with a cooling method using radiational cooling.

### SUMMARY

In the vacuum film deposition apparatus in JP 2003-247067 A, the cooling zones are provided inside the vacuum case and are in a vacuum. In a vacuum, the cooling efficiency decreases in comparison with that in the atmospheric pressure, and therefore, it takes time to cool the substrate to a desired temperature. Further, in a case where the installation length of a cooling chamber is lengthened to increase the retention time in the cooling zone, the whole facility is upsized.

The present disclosure has been accomplished in consideration of such a problem, and an object of the present disclosure is to provide a film deposition apparatus that can improve cooling efficiency.

A film deposition apparatus according to one aspect is a film deposition apparatus including a depressurized processing vessel in which a film deposition chamber and a cooling chamber communicating with the film deposition chamber are provided, the film deposition chamber being configured to perform vacuum deposition on a substrate, the cooling chamber being configured to cool the substrate. The cooling chamber includes: a passage through which the substrate moves; and a cooling device placed on an inner wall of the processing vessel, the cooling device including a surface-area expansion structure portion facing the passage and a refrigerant passage for refrigerant.

A film deposition apparatus according to another aspect is a film deposition apparatus including: a film deposition chamber configured to perform vacuum deposition on a substrate; and a cooling chamber configured to cool the substrate, the cooling chamber communicating with the film deposition chamber and having a pressure higher than a pressure of the film deposition chamber. The film deposition chamber and the cooling chamber are provided in a depressurized processing vessel.

A film deposition apparatus according to another aspect is a film deposition apparatus including a depressurized processing vessel in which a film deposition chamber and a cooling chamber communicating with the film deposition chamber are provided, the film deposition chamber being configured to perform vacuum deposition on a substrate, the cooling chamber being configured to cool the substrate. The cooling chamber includes: a cooling vessel filled with a plurality of metal balls made of the same material as a film deposition material or a material containing the film deposition material, the cooling vessel being configured to hold the substrate in a state where the substrate is surrounded by the metal balls; and a cooling device configured to cool the cooling vessel.

With the present disclosure, it is possible to provide a film deposition apparatus that can improve cooling efficiency.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a view illustrating a configuration of a film deposition apparatus according to Embodiment 1;

FIG. 2 is a view illustrating a first example of a cooling device provided in a cooling chamber in FIG. 1;

FIG. 3 is a view illustrating a second example of the cooling device provided in the cooling chamber in FIG. 1;

FIG. 4 is a view illustrating a third example of the cooling device provided in the cooling chamber in FIG. 1;

FIG. 5 is a view illustrating a configuration of a film deposition apparatus according to Embodiment 2;

FIG. 6 is a view illustrating a configuration of a film deposition apparatus according to Embodiment 3;

FIG. 7 is a view illustrating an example of a cooling vessel provided in a cooling chamber in FIG. 6; and

FIG. 8 is a view illustrating changes in a workpiece temperature in a case where the film deposition apparatuses according to Embodiments 1 to 3 are used.

### DETAILED DESCRIPTION OF EMBODIMENTS

With reference to drawings, the following describes embodiments of the present disclosure. The following description and drawings are omitted or simplified appropriately for clarification of the description. In the drawings, the same reference sign is assigned to the same element, and redundant descriptions are omitted as needed. Note that the disclosure according to Claims is not limited to the following embodiments, and all constituents described in the embodiments are not necessarily essential as the means for solving the problem of the disclosure.

### Embodiment 1

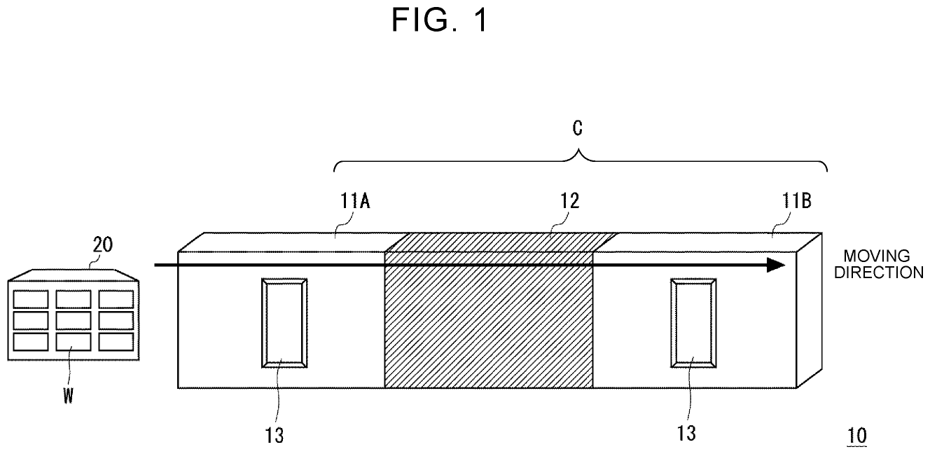

FIG. 1 is a view illustrating a configuration of a film deposition apparatus 10 according to Embodiment 1. The film deposition apparatus 10 is a vacuum film deposition apparatus for forming a film on a workpiece (substrate) W in a vacuum. Such a vacuum film deposition apparatus is a physical vapor deposition apparatus such as an ion plating apparatus or a sputtering apparatus, or a chemical vapor deposition apparatus. For example, a titanium film is formed by use of the sputtering apparatus as follows. That is, while inert gas (e.g., Ar gas) is introduced into a vacuum chamber (a processing vessel), direct voltage is applied between a workpiece and a target (a film deposition material Ti) such that ionic Ar hits the target, and titanium particles flicked out are attached and deposited on the surface of the workpiece.

The example illustrated in FIG. 1 is an in-line type film deposition apparatus 10. In the film deposition apparatus 10, film deposition is performed at the same time on a plurality of workpieces W held by a holder 20. As illustrated in FIG. 1, the film deposition apparatus 10 includes film deposition chambers 11A, 11B, and a cooling chamber 12. The film deposition chamber 11A, the cooling chamber 12, and the film deposition chamber 11B are placed sequentially from the upstream side along the moving direction of the holder 20 as indicated by an arrow in FIG. 1. Although not illustrated herein, a load lock chamber, a pretreatment chamber, and the like may be provided before the film deposition chamber 11A, and a post-treatment chamber, a load lock chamber, and the like may be provided after the film deposition chamber 11B.

The film deposition chambers 11A, 11B and the cooling chamber 12 are provided in a depressurized processing vessel C. The cooling chamber 12 communicates with the film deposition chambers 11A, 11B. When the holder 20 moves in the direction indicated by the arrow in FIG. 1 and passes through the film deposition chamber 11A and the film deposition chamber 11B, films are formed on the workpieces W.

For example, in the physical vapor deposition device, workpieces are processed at a temperature of around 200° C. to 600° C., and therefore, the temperature of the workpieces also gradually increases in the course of a deposition process. In the in-line type vacuum film deposition apparatus, in order to shorten the processing time, a plurality of evaporation sources 13 is provided, or the output of the evaporation sources is increased, so that the temperature of workpieces remarkably increases.

In a case where a material such as stainless steel or aluminum is used for the workpieces, the following problem is caused. That is, a temperature increase causes sensitization (a decrease in corrosion resistance), softening, or a decrease in rigidity due to coarsening or the like of crystalline particles. Further, at a high workpiece temperature, film deposition on resin or the like becomes difficult practically. On that account, time to decrease the workpiece temperature is required before and after the deposition process. The cooling chamber 12 is provided to decrease such a workpiece temperature.

Generally, a cooling chamber is placed in the same processing vessel as a film deposition chamber such that the cooling chamber communicates with the film deposition chamber in a vacuum state. However, the cooling chamber in a vacuum state has poor cooling efficiency similarly to vacuum bottles, and it takes time to decrease the temperature of the workpiece W to a predetermined temperature. Accordingly, it is necessary to enlarge (lengthen) the cooling chamber, thereby resulting in that the installation area for a processing vessel (a vacuum chamber) including the cooling chamber increases. This accordingly increases capital investment costs increase. That is, there is such a problem that costs for product processing increase.

In view of this, the inventors of the present disclosure devised a configuration that can improve the cooling efficiency of the cooling chamber 12. As the way of heat traveling, there are three ways: (1) radiation; (2) convection; and (3) conduction. The temperature of the workpiece W can be decreased solely by any of the three ways or by a combination of any of them. In the embodiments, the cooling chamber 12 that employs the ways (1) to (3) is provided between the film deposition chamber 11A and the film deposition chamber 11B in the in-line vacuum film deposition apparatus. The following describes a concrete configuration of the cooling chamber 12.

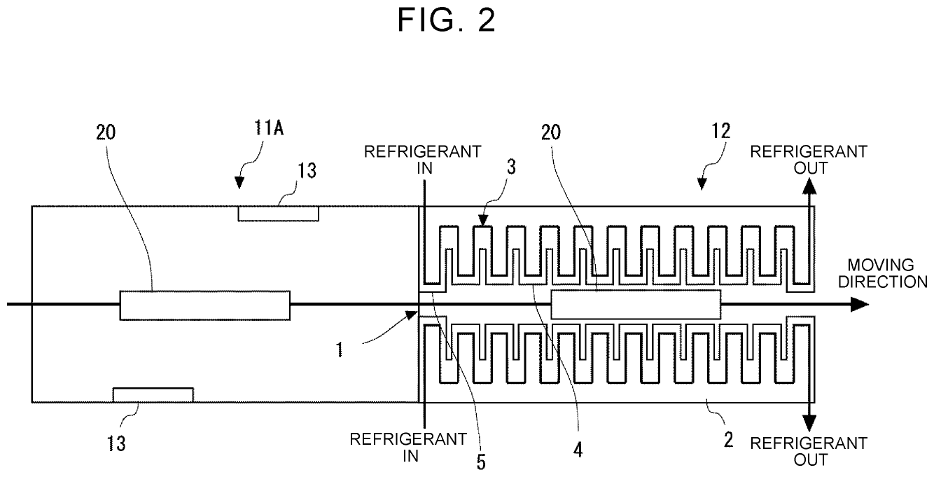

In Embodiment 1, the cooling chamber 12 cools the workpiece W by radiation. FIG. 2 is a view illustrating a first example of the film deposition apparatus 10 provided in the cooling chamber 12 in FIG. 1. FIG. 2 illustrates a view of the film deposition apparatus 10 viewed from above. Note that, here, only the film deposition chamber 11A and the cooling chamber 12 are illustrated.

As illustrated in FIG. 2, the film deposition chamber 11A is provided with two evaporation sources 13. A first one of the evaporation sources 13 is placed on a right inner wall and a second one of the evaporation sources 13 is placed on a left inner wall sequentially along the moving direction of the holder 20.

The cooling chamber 12 includes a passage 1 and cooling devices 2. In the cooling chamber 12, the cooling devices 2 are placed on inner walls of the processing vessel C. In the example illustrated in FIG. 2, the cooling devices 2 are placed on right and left inner walls of the processing vessel C, respectively, when the cooling devices 2 are viewed from the moving direction of the holder 20. Note that the cooling devices 2 may be placed on upper and lower inner walls of the processing vessel C or may be placed on the right, left, upper, and lower inner walls such that the passage 1 is surrounded by the cooling devices 2.

The passage 1 is formed between the cooling devices 2. The holder 20 configured to hold the workpieces W that have been subjected to the deposition process in the film deposition chamber 11A passes through the passage 1 to move toward the film deposition chamber 11B. The workpiece W is cooled by the cooling devices 2 by passing through the passage 1.

The cooling device 2 includes a refrigerant passage 3, a projecting portion 4, and an overhanging portion 5. The cooling device 2 circulates refrigerant such as coolant through the refrigerant passage 3. The refrigerant supplied to a first end of the refrigerant passage 3 from outside passes through the refrigerant passage 3 and is then discharged to outside from a second end of the refrigerant passage 3. The refrigerant circulating through the refrigerant passage 3 and the workpiece W exchange heat with each other, so that the heat of the workpiece W is discharged to outside via the refrigerant, and hereby, the workpiece W is cooled.

The projecting portion 4 and the overhanging portion 5 are formed on a surface of the cooling device 2, the surface facing the passage 1. The projecting portion 4 and the overhanging portion 5 constitute a surface-area expansion structure portion. The projecting portion 4 and the overhanging portion 5 are provided to improve the cooling efficiency for the workpiece W by expanding the surface area. A plurality of projecting portions 4 is provided to project toward the passage 1 from the inner wall of the processing vessel C. The refrigerant passage 3 is formed in a zigzag manner along the projecting portions 4.

By increasing the surface area by the surface-area expansion structure portion and providing the refrigerant passage 3 along the surface-area expansion structure portion as such, it is possible to increase an effect of the cooling device 2 to absorb the temperature inside the cooling chamber 12. Hereby, it is possible to improve the cooling efficiency for the workpiece W in the cooling chamber 12 without lengthening the installation length.

The overhanging portion 5 is formed in either end part of the surface-area expansion structure portion, the either end part being on a side closer to the film deposition chamber 11A, 11B. The overhanging portion 5 overhangs in a direction narrowing the width of the passage 1. That is, the height of the overhanging portion 5 is higher than the height of the projecting portion 4. Hereby, it is possible to trap, by the overhanging portion 5, deposition particles from the evaporation sources 13 of the film deposition chambers 11A, 11B, thereby making it possible to prevent the deposition particles from being attached inside the cooling chamber 12. Note that the surface-area expansion structure portion may have a labyrinth structure in which a maze is formed.

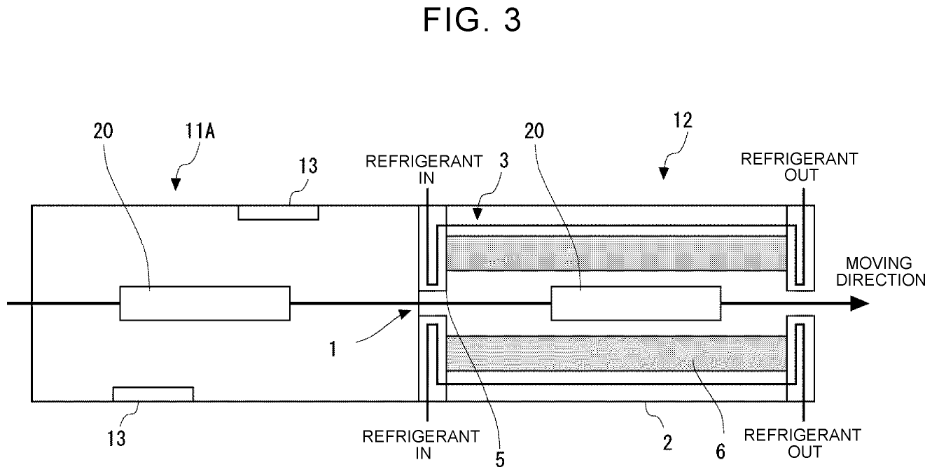

FIG. 3 is a view illustrating a second example of the cooling device provided in the cooling chamber in FIG. 1. FIG. 3 is different from FIG. 2 in that a foam metal 6 including opened cavities is provided instead of the projecting portions 4. The foam metal 6 including the opened cavities can enlarge the surface area. Hereby, it is possible to improve the coolability of the cooling device 2. Note that the foam metal 6 may include closed cavities.

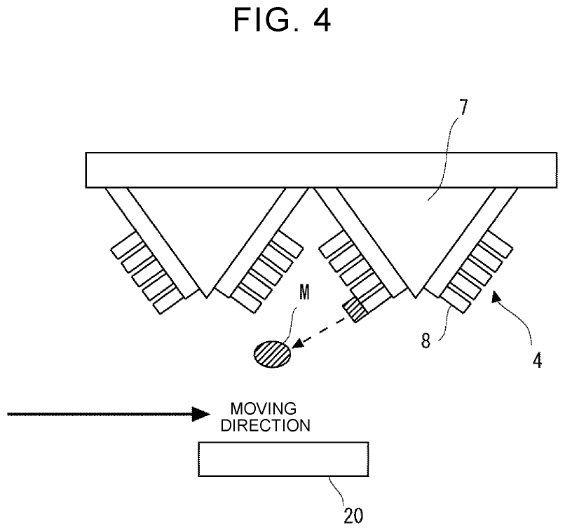

FIG. 4 is a view illustrating a third example of the cooling device provided in the cooling chamber in FIG. 1. FIG. 4 illustrates another example of the projecting portions 4 in detail. As illustrated in FIG. 4, the projecting portion 4 includes a base portion 7 and branch portions 8.

The base portion 7 is a triangle pole the section of which has a triangular shape projecting toward the passage 1. A direction where the side face of the base portion 7 extends is perpendicular to the moving direction of the holder 20 that moves from the film deposition chamber 11A to the cooling chamber 12. The side faces of the projecting portion 4 are inclined to the surface of the workpiece W. Further, a plurality of branch portions 8 is provided to project from the base portion 7.

A film deposition material M flying from the film deposition chamber 11A and attached to the inner wall of the cooling chamber 12 naturally peels off from the inner wall when the film deposition material M is deposited thick. In the example illustrated in FIG. 4, the side faces of the projecting portion 4 are inclined from the surface of the workpiece W. Accordingly, when the film deposition material M peels off, the film deposition material M can be prevented from jumping out to a direction directed to the holder 20. This can restrain the peeled film deposition material M from being attached to the workpiece W, thereby making it possible to improve the yield.

Further, in the example of FIG. 4, since the branch portions 8 are provided on the surface of the base portion 7, the base portion 7 has a recess-projection shape and is thus subjected to surface roughening. Since the surface of the projecting portion 4 is roughed as such, the film deposition material M is hard to peel off from the surface of the projecting portion 4. This decreases the frequency of peeling of the film deposition material M, thereby making it possible to further restrain the film deposition material M from being attached to the workpiece W. Thus, in the cooling chamber 12, the peeled film deposition material M is not attached to the workpiece W, and hereby, it is possible to omit a smoothing process on a formed film after the film is formed. Further, it is possible to reduce negative factors to be caused by the peeled film deposition material M, e.g., a defect or the like to be caused when the peeled film deposition material M attached to a substrate is peeled off.

Note that, as the surface roughening of the projecting portion 4, a satin shape by a sandblast process or the like may be formed on the surface of the projecting portion 4 instead of forming the branch portions 8. Further, the surface roughening may be performed on the surface of the projecting portion 4 in the first example.

Further, in the cooling chamber 12, it is desirable that the inner wall of the processing vessel C and the surface-area expansion structure portion (the projecting portions 4, the overhanging portions 5) that face the workpiece W be black. When a black material having a black-body radiation effect is used, the heat conductance of the inner wall of the processing vessel C and the surface-area expansion structure portion in the cooling chamber 12 increases, thereby making it possible to improve the cooling efficiency for the workpiece W. Note that, the overhanging portion 5 catches the deposition particles, and therefore, a part of the overhanging portion 5 may become silver due to deposition of the film deposition material (titanium). However, the surface of the overhanging portion 5 except the part where the film deposition material is deposited can be maintained to be black.

### Embodiment 2

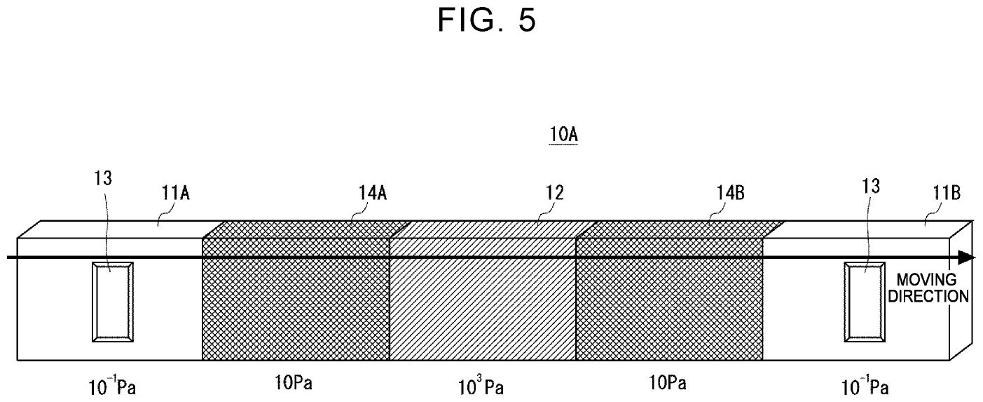

In Embodiment 2, the cooling chamber 12 cools the workpiece W by convection. FIG. 5 is a view illustrating a configuration of a film deposition apparatus 10A according to Embodiment 2. FIG. 5 is different from FIG. 1 in that a pressure control chamber 14A is provided between the film deposition chamber 11A and the cooling chamber 12, and a pressure control chamber 14B is provided between the cooling chamber 12 and the film deposition chamber 11B.

As illustrated in FIG. 2, the film deposition apparatus 10A includes the film deposition chambers 11A, 11B, the cooling chamber 12, and the pressure control chambers 14A, 14B. The film deposition chamber 11A, the pressure control chamber 14A, the cooling chamber 12, the pressure control chamber 14B, and the film deposition chamber 11B are placed sequentially from the upstream side along the moving direction of the holder 20 as indicated by an arrow in FIG. 5. The film deposition chambers 11A, 11B, the cooling chamber 12, and the pressure control chambers 14A, 14B are provided in the depressurized processing vessel C. The cooling chamber 12 communicates with the pressure control chambers 14A, 14B. The pressure control chamber 14A communicates with the film deposition chamber 11A, and the pressure control chamber 14B communicates with the film deposition chamber 11B. When the holder 20 moves in the direction indicated by the arrow in FIG. 5 and passes through the film deposition chamber 11A and the film deposition chamber 11B, films are formed on the workpieces W.

Although not illustrated herein, a refrigerant passage through which refrigerant circulates is provided in the inner wall of the processing vessel C constituting the cooling chamber 12, and the inner wall of the processing vessel C itself functions as a cooling device.

The pressure of the cooling chamber 12 is higher than the pressures of the film deposition chambers 11A, 11B. For example, the pressures of the film deposition chambers 11A, 11B are 10⁻¹ Pa, and the pressure of the cooling chamber 12 is 10³ Pa. The pressure of the cooling chamber 12 can be made higher than the pressures of the film deposition chambers 11A, 11B by use of inert gas (rare gas such as argon or helium, hydrogen, nitrogen, or the like), for example.

When the pressure of the cooling chamber 12 is made higher than the pressures of the film deposition chambers 11A, 11B as such, it is possible to improve the cooling efficiency in comparison with a case where the cooling chamber is in the same vacuum state as the film deposition chambers, thereby making it possible to cool the workpiece W without lengthening the installation length.

Further, the pressure control chamber 14A is provided between the film deposition chamber 11A and the cooling chamber 12, and the pressure control chamber 14B is provided between the cooling chamber 12 and the film deposition chamber 11B. The pressures of the pressure control chambers 14A, 14B are higher than the pressures of the film deposition chamber 11A, 11B and lower than the pressure of the cooling chamber 12. When the pressure control chambers 14A, 14B are provided as such, the pressure in the cooling chamber 12 can be made further higher, thereby making it possible to further improve the cooling efficiency of the cooling chamber 12.

### Embodiment 3

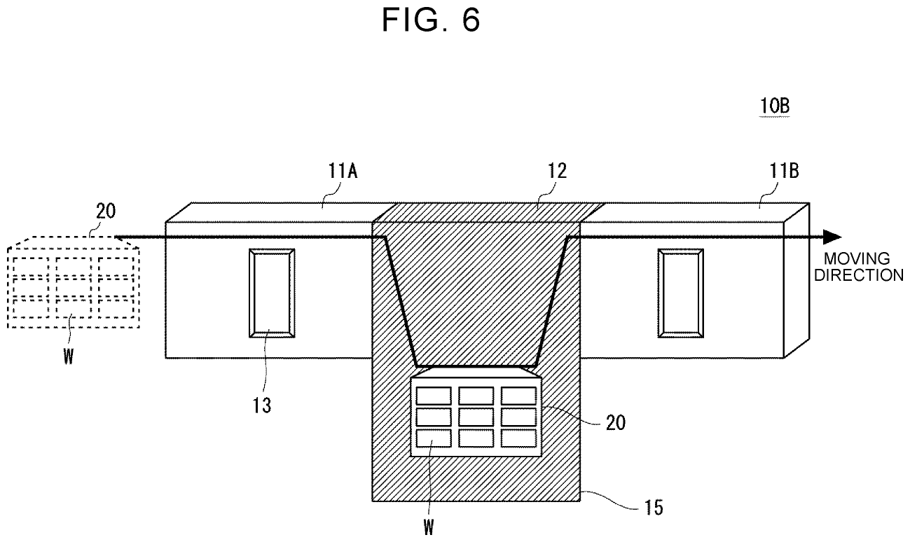

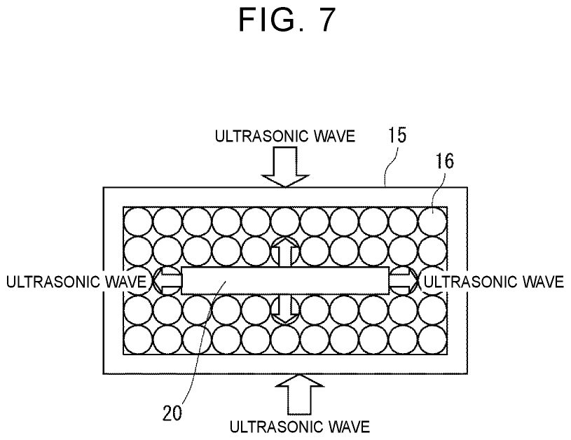

In Embodiment 3, the cooling chamber 12 cools the workpiece W by conduction. FIG. 6 is a view illustrating a configuration of a film deposition apparatus 10B according to Embodiment 3. FIG. 7 is a view illustrating an example of a cooling vessel provided in the cooling chamber 12 in FIG. 6. FIG. 6 is different from FIG. 1 in that a cooling vessel 15 for cooling the workpiece W is provided in the cooling chamber 12.

A refrigerant passage (not illustrated) through which refrigerant circulates is provided in the cooling vessel 15, and the wall of the cooling vessel 15 itself functions as a cooling device. As illustrated in FIG. 7 the cooling vessel 15 is filled with a plurality of metal balls 16 made of a material (alloy) that is the same as the film deposition material or that contains the film deposition material. Herein, a titanium film is formed, so that titanium is used as the material of the metal balls 16.

Note that the shape of the metal balls 16 does not necessarily need to be a true sphere, and the shape of the metal balls 16 may be an oval shape or may have some distortions. The metal balls 16 overlap with each other in a plurality of layers inside the cooling vessel 15, but a gap is formed between adjacent metal balls 16. The diameter of the metal ball 16 (or the maximum dimension across the metal ball 16) can be changed in accordance with the shape of the workpiece W. For example, in a case where a groove is provided in the workpiece W, the size of the metal ball 16 can be made larger than the groove (e.g., 1 mm).

The metal balls 16 may all have the same diameter or may include a plurality of metal balls having different diameters. For example, the metal balls 16 can include metal balls 16 having diameters of 1 mm, 5 mm, and 10 mm.

The holder 20 holding the workpiece W is held in a state where the holder 20 is surrounded by the metal balls 16 inside the cooling vessel 15. The metal balls 16 are freely movable inside the cooling vessel 15 without being restricted. Accordingly, each of the metal balls 16 can be arranged freely. This allows the metal balls 16 to have a large contact area with the workpiece W, thereby making it possible to cool the workpiece W by conduction without lengthening the installation length.

Further, it is preferable to include an ultrasonic generator configured to apply an ultrasonic wave to at least either of the cooling vessel 15 and the holder 20 holding the workpiece W. In a state where the ultrasonic wave is applied to at least either one of the cooling vessel 15 and the workpiece W, the workpiece W (the substrate) is put in or out of the metal balls 16. Hereby, it is possible to reduce a resistance at the time when the holder 20 is put in or out, thereby making it possible to restrain the workpiece W from being damaged. Further, at the time when the holder 20 is taken out from the cooling vessel 15, it is possible to remove the metal balls 16 attached to the holder 20.

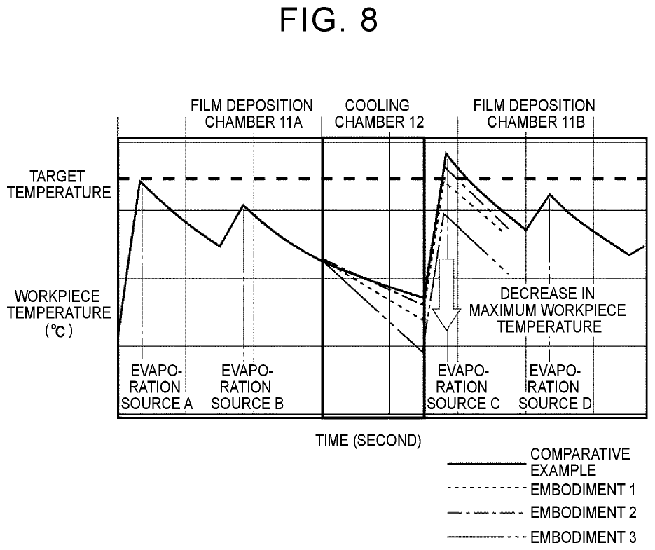

FIG. 8 is a view illustrating changes in a workpiece temperature in a case where the film deposition apparatuses according to Embodiments 1 to 3 are used. The film deposition chambers 11A, 11B are each provided with two evaporation sources 13. Evaporation sources A, B, C, D are provided sequentially from the upstream side along the moving direction of the holder 20. Note that an example in which the workpiece is cooled naturally in a case where the cooling chamber is in the same vacuum state as the film deposition chambers is taken as a comparative example.

As illustrated in FIG. 8 in any of Embodiments 1 to 3, the temperature of workpiece W was decreased more than the comparative example without lengthening the installation length. Further, the maximum workpiece temperature was decreased to a temperature below a target temperature set in advance.

Note that the disclosure is not limited to the above embodiments, and various modifications can be made within a range that does not deviate from the gist of the disclosure. For example, Embodiment 1 may be combined with Embodiment 2 such that the cooling device including the surface-area expansion structure portion is provided, and the pressure of the cooling chamber 12 is higher than the pressures of the film deposition chambers 11A, 11B. Further, Embodiment 2 may be combined with Embodiment 3 such that the cooling vessel filled with the metal balls is provided, and the pressure of the cooling chamber 12 is higher than the pressures of the film deposition chambers 11A, 11B.

What is claimed is:

1. A film deposition apparatus including a depressurized processing vessel in which a film deposition chamber and a cooling chamber communicating with the film deposition chamber are provided, the film deposition chamber being configured to perform vacuum deposition on a substrate, the cooling chamber being configured to cool the substrate, wherein the cooling chamber includes:
a passage through which the substrate moves; and
a cooling device placed on an inner wall of the processing vessel, the cooling device including a surface-area expansion structure portion facing the passage and a refrigerant passage for refrigerant.

2. The film deposition apparatus according to claim 1, wherein:
the surface-area expansion structure portion includes a plurality of projecting portions provided to project toward the passage from the inner wall of the processing vessel; and
the refrigerant passage is formed along the projecting portions.

3. The film deposition apparatus according to claim 2, wherein the projecting portions each include a base portion having a triangle pole shape with a triangular section projecting toward the passage, the base portion being provided such that an extending direction of a side face of the base portion is perpendicular to a moving direction of the substrate moving from the film deposition chamber to the cooling chamber.

4. The film deposition apparatus according to claim 3, wherein the projecting portions each further include branch portions projecting from the base portion.

5. The film deposition apparatus according to claim 2, wherein surfaces of the projecting portions are subjected to surface roughening.

6. The film deposition apparatus according to claim 1, wherein the surface-area expansion structure portion includes a foam metal including opened cavities.

7. The film deposition apparatus according to claim 1, wherein an end portion, on the film deposition chamber side, of the surface-area expansion structure portion includes an overhanging portion provided to overhang in a direction narrowing a width of the passage.

8. The film deposition apparatus according to claim 1, wherein the inner wall of the processing vessel and the surface-area expansion structure portion in the cooling chamber are black.

9. A film deposition apparatus comprising:
a film deposition chamber configured to perform vacuum deposition on a substrate; and
a cooling chamber configured to cool the substrate, the cooling chamber communicating with the film deposition chamber and having a pressure higher than a pressure of the film deposition chamber, wherein the film deposition chamber and the cooling chamber are provided in a depressurized processing vessel.

10. The film deposition apparatus according to claim 9, further comprising a pressure control chamber provided between the film deposition chamber and the cooling chamber, the pressure control chamber having a pressure higher than the pressure of the film deposition chamber and lower than the pressure of the cooling chamber.

11. A film deposition apparatus including a depressurized processing vessel in which a film deposition chamber and a cooling chamber communicating with the film deposition chamber are provided, the film deposition chamber being configured to perform vacuum deposition on a substrate, the cooling chamber being configured to cool the substrate, wherein the cooling chamber includes:
a cooling vessel filled with a plurality of metal balls made of the same material as a film deposition material or a material containing the film deposition material, the cooling vessel being configured to hold the substrate in a state where the substrate is surrounded by the metal balls; and
a cooling device configured to cool the cooling vessel.

12. The film deposition apparatus according to claim 11, wherein the metal balls include a plurality of metal balls having different diameters.

13. The film deposition apparatus according to claim 11, further comprising an ultrasonic generator configured to apply an ultrasonic wave to at least either one of the cooling vessel and the substrate, wherein the substrate is put in or out of the metal balls in a state where the ultrasonic wave is applied to the at least either one of the cooling vessel and the substrate.
